(19) United States
(12) Patent Application Publication
(10) Pub. No.: US 2024/0283464 A1
(43) Pub. Date: Aug. 22, 2024

(54) ROBUSTNESS WHEN USING APPLICATION LAYER FORWARD ERROR CORRECTION (AL-FEC) IN AN ATSC3 RECEIVER

(71) Applicant: Sony Group Corporation, Tokyo (JP)

(72) Inventors: Graham Clift, San Diego, CA (US); Luke Fay, San Diego, CA (US)

(73) Assignee: Sony Group Corporation, Tokyo (JP)

(21) Appl. No.: 18/186,776

(22) Filed: Mar. 20, 2023

Related U.S. Application Data
(60) Provisional application No. 63/486,284, filed on Feb. 22, 2023.

(51) Int. Cl. H03M 13/09

(52) U.S. Cl. CPC H03M 13/096

(57) ABSTRACT

Techniques are described for expanding and/or improving the Advanced Television Systems Committee (ATSC) 3.0 television protocol in robustly delivering the next generation broadcast television services. To improve robustness for datacast files, a checksum is provided for each source block in the file, allowing the receiver to discard only a portion of the data as defined by the length of a corrupted block in the AL-FEC parameters. A list of checksums for each source block can be included in the RepairFlow element of the service transport session instance description (S-TSID) since RepairFlow element and AL-FEC provide the breakdown of the data into source blocks.

### FIELD

This application relates to technical advances necessarily rooted in computer technology and directed to digital television, and more particularly to Advanced Television Systems Committee (ATSC) 3.0.

### BACKGROUND

The Advanced Television Systems Committee (ATSC) 3.0 suite of standards is a set of over a dozen industry technical standards as indicated in A/300 for delivering the next generation of broadcast television. ATSC 3.0 supports delivery of a wide range of television services including televised video, interactive services, non-real time delivery of data, and tailored advertising to a large number of receiving devices, from ultra-high definition televisions to wireless telephones. ATSC 3.0 also orchestrates coordination between broadcast content (referred to as “over the air”) and related broadband delivered content and services (referred to as “over the top”). ATSC 3.0 is designed to be flexible so that as technology evolves, advances can be readily incorporated without requiring a complete overhaul of any related technical standard.

As understood herein, ATSC 3.0 can be used to deliver data to mobile receivers, such as delivering maps or operating manuals to moving vehicles. Error correction techniques can be applied to improve data reception.

### SUMMARY

As understood herein, application layer forward error correction (AL-FEC) in ATSC3 is specified in the ATSC standard A/331 to use the error correction technique described in publication RFC 6330 (“RaptorQ”) for packet data repair when data repair is desirable. Repair data is advantageous in datacasting where file delivery is especially sensitive to packet loss. Error concealment in video is mature, but file delivery needs all packets correctly received to complete the reception of a file. Large file delivery is of interest in many use-cases, including to platforms that do not have ample amount of CPU processing speed. Raptor-Q packet repair is computationally intensive and present principles address that requirement by breaking up files into smaller pieces that can be processed separately.

Each delivered collection of packets (file partition) can have associated repair bytes, but if the repair is incorrect, the ATSC3 receiver of the data may have no knowledge that this data is incorrect unless a single overall MD5 checksum is included in the FDT-Instance signaling inside the S-TSID table. This can cause incorrect repair operation or no repair operation of the file partition which can result in significant delays of correct reception of large files. For NRT data delivery, even a single incorrect bit of data may make it unusable suggesting this checksum is critical to correct file partitions when they are received and not wait for file carousels to provide the data (file partition) again. Present principles recognize, however, that a single overall checksum provides minimal information regarding location of the bad data and thus all data will need to be discarded and the receiver will need to begin the reception again (assuming the data, as is typical in broadcast scenarios, is on a carousel) of that specific file partition.

Accordingly, present principles apply a checksum on a per source block (file partition) basis to minimize the effort required of a receiver to correct packet errors/losses by improving the likelihood of success after further attempts around a carousel where sufficient repair blocks may not always be available for every source block. This is especially true with large files. In addition, the receiver may supplement the missing packets and bad source blocks through a TCP/IP connection when a server, and the connection to the server, is available, by requesting repair packets whilst minimizing the data overhead on the unicast server.

To improve robustness, it is therefore useful for the receiver to receive a checksum for each source block allowing the receiver to only discard a portion of the data as defined by the length of this source block in the AL-FEC parameters.

A list of checksums may be included and correlated, for each checksum, to the source block to which it applies. In one embodiment, the list of checksums is included in the RepairFlow element of the service transport session instance description (S-TSID) since only RepairFlow element and AL-FEC provides the breakdown of the data into source blocks and has no meaning outside of RepairFlow element.

In an embodiment, a broadcaster supplies a cyclic redundancy check (CRC)32 checksum (shortest reliable checksum) for each source block in the S-TSID/RepairFlow element when AL-FEC is supported. A receiver verifies the checksum of each source block and, if invalid, either fetches the source block data from a server (as location specified in other signaling) or waits to receive the data again on a broadcast carousel.

Present principles also apply to file delivery in other multicast distribution methods where RFC 6330 (RAPTOR-Q) is used.

Accordingly, in datacasting, a method includes computing respective cyclic redundancy code (CRC) 32 bit checksums for each source block of a digital file. The method further includes transmitting the source blocks and a list of the checksums to at least one receiver using digital television transmission of ATSC 3.0. The list is included in a RepairFlow element of a service transport session instance description (S-TSID).

In some embodiments, the method can further include, at an ATSC 3.0 datacasting receiver, applying a checksum on a per source block basis to improve likelihood of success after further attempts around a broadcast carousel. This can be done at least in part by receiving the source blocks and the list of checksums, verifying each checksum, and discarding source blocks for which the respective checksums are not verified. Source blocks for which the respective checksums are verified are not discarded. The method may further include, for source blocks with unverified checksums, fetching the source blocks from at least one server having a network location specified in the S-TSID, or waiting to receive the source blocks again on a broadcast carousel, or both.

In some examples verifying each checksum can include recomputing the checksum using content of the respective source block and comparing the recomputed checksum with the checksum for the source block as received in the list.

In another aspect, a datacasting apparatus includes at least one receiver configured to receive digital television from a digital television transmitter system. The receiver in turn includes at least one processor programmed with instructions for receiving plural source blocks of at least one file and a list of respective checksums associated with the source blocks from at least one digital television transmitter. The processor is configured for verifying each checksum and discarding source blocks for which the respective checksums are not verified. Source blocks for which the respective checksums are verified are not discarded. For source blocks with unverified checksums, the instructions are executable fetching the source blocks from at least one server having a network location specified in signaling of the digital television, or waiting to receive the source blocks again on a broadcast carousel, or both fetching the source blocks from the at least one server and waiting to receive the source blocks again on a broadcast carousel.

In another aspect, a digital television apparatus includes at least one transmitter that in turn includes at least one processor programmed with instructions to configure the processor for computing respective checksums for each source block of a digital file, and transmitting the source blocks and a list of the checksums to at least one receiver using digital television transmission.

The details of the present application, both as to its structure and operation, can best be understood in reference to the accompanying drawings, in which like reference numerals refer to like parts, and in which:

### BRIEF DESCRIPTION OF THE DRAWINGS

FIG. 1 illustrates an Advanced Television Systems Committee (ATSC) 3.0 system;

FIG. 2 illustrates components of the devices shown in FIG. 1;

FIG. 3 illustrates an example transmitter side architecture;

FIG. 4 illustrates an example receiver side architecture;

FIG. 5 illustrates example transmitter logic consistent with present principles; and

FIG. 6 illustrates example receiver logic consistent with present principles.

### DETAILED DESCRIPTION

This disclosure relates to technical advances in digital television such as in Advanced Television Systems Committee (ATSC) 3.0 television. An example system herein may include ATSC 3.0 source components and client components, connected via broadcast and/or over a network such that data may be exchanged between the client and ATSC 3.0 source components. The client components may include one or more computing devices including portable televisions (e.g. smart TVs, Internet-enabled TVs), portable computers such as laptops and tablet computers, and other mobile devices including smart phones and additional examples discussed below. These client devices may operate with a variety of operating environments. For example, some of the client computers may employ, as examples, operating systems from Microsoft, or a Unix operating system, or operating systems produced by Apple Computer or Google, such as Android®. These operating environments may be used to execute one or more browsing programs, such as a browser made by Microsoft or Google or Mozilla or other browser program that can access websites hosted by the Internet servers discussed below.

ATSC 3.0 publication A/331, Annex A, incorporated herein by reference, may be particularly relevant to techniques described herein.

ATSC 3.0 source components may include broadcast transmission components and servers and/or gateways that may include one or more processors executing instructions that configure the source components to broadcast data and/or to transmit data over a network such as the Internet. A client component and/or a local ATSC 3.0 source component may be instantiated by a game console such as a Sony PlayStation®, a personal computer, etc.

Information may be exchanged over a network between the clients and servers. To this end and for security, servers and/or clients can include firewalls, load balancers, temporary storages, and proxies, and other network infrastructure for reliability and security.

As used herein, instructions refer to computer-implemented steps for processing information in the system. Instructions can be implemented in software, firmware or hardware and include any type of programmed step undertaken by components of the system.

A processor may be a single-or multi-chip processor that can execute logic by means of various lines such as address lines, data lines, and control lines and registers and shift registers.

Software modules described by way of the flow charts and user interfaces herein can include various sub-routines, procedures, etc. Without limiting the disclosure, logic stated to be executed by a particular module can be redistributed to other software modules and/or combined together in a single module and/or made available in a shareable library. While flow chart format may be used, it is to be understood that software may be implemented as a state machine or other logical method.

Present principles described herein can be implemented as hardware, software, firmware, or combinations thereof; hence, illustrative components, blocks, modules, circuits, and steps are set forth in terms of their functionality.

Further to what has been alluded to above, logical blocks, modules, and circuits can be implemented or performed with a general-purpose processor, a digital signal processor (DSP), a field programmable gate array (FPGA) or other programmable logic device such as an application specific integrated circuit (ASIC), discrete gate or transistor logic, discrete hardware components, or any combination thereof designed to perform the functions described herein. A processor can be implemented by a controller or state machine or a combination of computing devices.

The functions and methods described below, when implemented in software, can be written in an appropriate language such as but not limited to hypertext markup language (HTML)-5, Java®/Javascript, C #or C++, and can be stored on or transmitted through a computer-readable storage medium such as a random access memory (RAM), read-only memory (ROM), electrically erasable programmable read-only memory (EEPROM), compact disk read-only memory (CD-ROM) or other optical disk storage such as digital versatile disc (DVD), magnetic disk storage or other magnetic storage devices including removable thumb drives, etc. A connection may establish a computer-readable medium. Such connections can include, as examples, hard-wired cables including fiber optics and coaxial wires and digital subscriber line (DSL) and twisted pair wires.

Components included in one embodiment can be used in other embodiments in any appropriate combination. For example, any of the various components described herein and/or depicted in the Figures may be combined, interchanged or excluded from other embodiments.

“An [element] having at least one of A, B, and C” (likewise “having at least one of A, B, or C” and “having at least one of A, B, C”) includes A alone, B alone, C alone, A and B together, A and C together, B and C together, and/or A, B, and C together, etc.

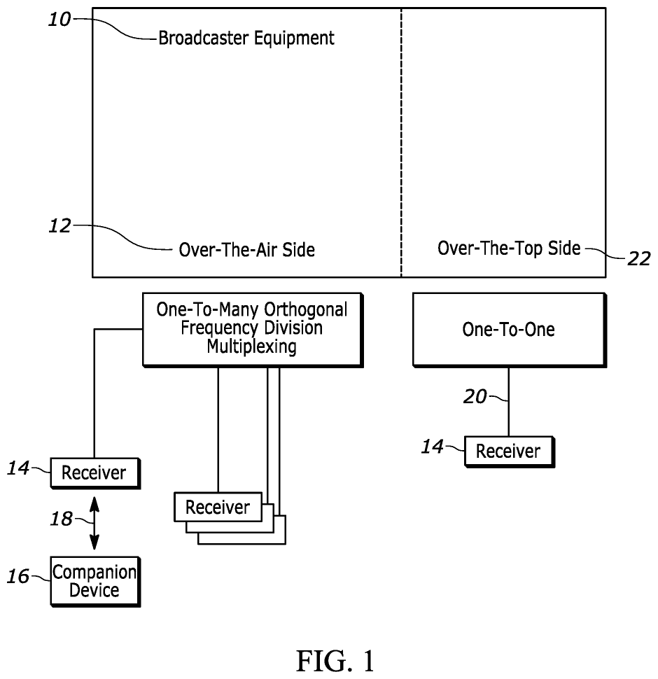

Turning to FIG. 1, an example of an ATSC 3.0 source component is labeled “broadcaster equipment” 10 and may include over-the-air (OTA) equipment 12 for wirelessly broadcasting, typically via orthogonal frequency division multiplexing (OFDM) in a one-to-many relationship, television data to plural receivers 14 such as ATSC 3.0 televisions. One or more receivers 14 may communicate with one or more companion devices 16 such as remote controls, tablet computers, mobile telephones, and the like over a short range, typically wireless link 18 that may be implemented by Bluetooth®, low energy Bluetooth, other near field communication (NFC) protocol, infrared (IR), etc.

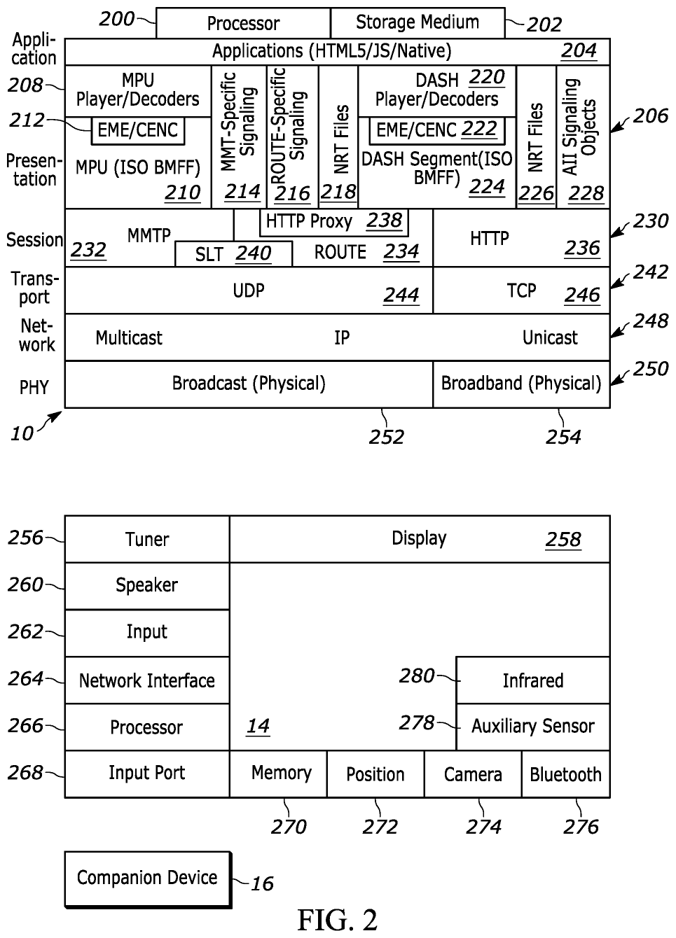

Also, one or more of the receivers 14 may communicate, via a wired and/or wireless network link 20 such as the Internet, with over-the-top (OTT) equipment 22 of the broadcaster equipment 10 typically in a one-to-one relationship. The OTA equipment 12 may be co-located with the OTT equipment 22 or the two sides 12, 22 of the broadcaster equipment 10 may be remote from each other and may communicate with each other through appropriate means. In any case, a receiver 14 may receive ATSC 3.0 television signals OTA over a tuned-to ATSC 3.0 television channel and may also receive related content, including television, OTT (broadband). Note that computerized devices described in all of the figures herein may include some or all of the components set forth for various devices in FIGS. 1 and 2.

Referring now to FIG. 2, details of examples of components shown in FIG. 1 may be seen. FIG. 2 illustrates an example protocol stack that may be implemented by a combination of hardware and software. Using the ATSC 3.0 protocol stack shown in FIG. 2 and modified as appropriate for the broadcaster side, broadcasters can send hybrid service delivery in which one or more program elements are delivered via a computer network (referred to herein as “broadband” and “over-the-top” (OTT)) as well as via a wireless broadcast (referred to herein as “broadcast” and “over-the-air” (OTA)). FIG. 2 also illustrates an example stack with hardware that may be embodied by a receiver.

Disclosing FIG. 2 in terms of broadcaster equipment 10, one or more processors 200 accessing one or more computer storage media 202 such as any memories or storages described herein may be implemented to provide one or more software applications in a top-level application layer 204. The application layer 204 can include one or more software applications written in, e.g., HTML5/Javascript running in a runtime environment. Without limitation, the applications in the application stack 204 may include linear TV applications, interactive service applications, companion screen applications, personalization applications, emergency alert applications, and usage reporting applications. The applications typically are embodied in software that represents the elements that the viewer experiences, including video coding, audio coding and the run-time environment. As an example, an application may be provided that enables a user to control dialog, use alternate audio tracks, control audio parameters such as normalization and dynamic range, and so on.

Below the application layer 204 is a presentation layer 206. The presentation layer 206 includes, on the broadcast (OTA) side, broadcast audio-video playback devices referred to as Media Processing Units (MPU) 208 that, when implemented in a receiver, decode and playback, on one or more displays and speakers, wirelessly broadcast audio video content. The MPU 208 is configured to present International Organization for Standardization (ISO) base media file format (BMFF) data representations 210 and video in high efficiency video coding (HEVC) with audio in, e.g., Dolby audio compression (AC-4) format. ISO BMFF is a general file structure for time-based media files broken into “segments” and presentation metadata. Each of the files is essentially a collection of nested objects each with a type and a length. To facilitate decryption, the MPU 208 may access a broadcast side encrypted media extension (EME)/common encryption (CENC) module 212.

FIG. 2 further illustrates that on the broadcast side the presentation layer 206 may include signaling modules, including either motion pictures expert group (MPEG) media transport protocol (MMTP) signaling module 214 or real-time object delivery over unidirectional transport (ROUTE) signaling module 216 for delivering non-real time (NRT) content 218 that is accessible to the application layer 204. NRT content may include but is not limited to stored replacement advertisements.

On the broadband (OTT or computer network) side, when implemented by a receiver the presentation layer 206 can include one or more dynamic adaptive streaming over hypertext transfer protocol (HTTP) (DASH) player/decoders 220 for decoding and playing audio-video content from the Internet. To this end the DASH player 220 may access a broadband side EME/CENC module 222. The DASH content may be provided as DASH segments 224 in ISO/BMFF format.

As was the case for the broadcast side, the broadband side of the presentation layer 206 may include NRT content in files 226 and may also include signaling objects 228 for providing play back signaling.

Below the presentation layer 206 in the protocol stack is a session layer 230. The session layer 230 includes, on the broadcast side, either MMTP protocol 232 or ROUTE protocol 234. Note that the ATSC standard provides an option to use MPEG MMT for transport, though it is not shown here.

On the broadband side the session layer 230 includes HTTP protocol 236 which may be implemented as HTTP-secure (HTTP(S)). The broadcast side of the session layer 230 also may employ a HTTP proxy module 238 and a service list table (SLT) 240. The SLT 240 includes a table of signaling information which is used to build a basic service listing and provide bootstrap discovery of the broadcast content. Media presentation descriptions (MPD) are included in the “ROUTE Signaling” tables delivered over user datagram protocol (UDP) by the ROUTE transport protocol.

A transport layer 242 is below the session layer 230 in the protocol stack for establishing low-latency and loss-tolerating connections. On the broadcast side the transport layer 242 uses (UDP 244 and on the broadband side transmission control protocol (TCP) 246.

The example non-limiting protocol stack shown in FIG. 2 also includes a network layer 248 below the transport layer 242. The network layer 248 uses Internet protocol (IP) on both sides for IP packet communication, with multicast delivery being typical on the broadcast side and unicast being typical on the broadband side.

Below the network layer 248 is the physical layer 250 which includes broadcast transmission/receive equipment 252 and computer network interface(s) 254 for communicating on the respective physical media associated with the two sides. The physical layer 250 converts Internet Protocol (IP) packets to be suitable to be transported over the relevant medium and may add forward error correction functionality to enable error correction at the receiver as well as contain modulation and demodulation modules to incorporate modulation and demodulation functionalities. This converts bits into symbols for long distance transmission as well as to increase bandwidth efficiency. On the OTA side the physical layer 250 typically includes a wireless broadcast transmitter to broadcast data wirelessly using orthogonal frequency division multiplexing (OFDM) while on the OTT side the physical layer 250 includes computer transmission components to send data over the Internet.

A DASH Industry Forum (DASH-IF) profile sent through the various protocols (HTTP/TCP/IP) in the protocol stack may be used on the broadband side. Media files in the DASH-IF profile based on the ISO BMFF may be used as the delivery, media encapsulation and synchronization format for both broadcast and broadband delivery.

Each receiver 14 typically includes a protocol stack that is complementary to that of the broadcaster equipment.

A receiver 14 in FIG. 1 may include, as shown in FIG. 2, an Internet-enabled TV with an ATSC 3.0 TV tuner (equivalently, set top box controlling a TV) 256. The receiver 14 may be an Android®-based system. The receiver 14 alternatively may be implemented by a computerized Internet enabled (“smart”) telephone, a tablet computer, a notebook computer, a wearable computerized device, and so on. Regardless, it is to be understood that the receiver 14 and/or other computers described herein is configured to undertake present principles (e.g. communicate with other devices to undertake present principles, execute the logic described herein, and perform any other functions and/or operations described herein).

Accordingly, to undertake such principles the receiver 14 can be established by some or all of the components shown in FIG. 1. For example, the receiver 14 can include one or more displays 258 that may be implemented by a high definition or ultra-high definition “4K” or higher flat screen and that may or may not be touch-enabled for receiving user input signals via touches on the display. The receiver 14 may also include one or more speakers 260 for outputting audio in accordance with present principles, and at least one additional input device 262 such as, e.g., an audio receiver/microphone for, e.g., entering audible commands to the receiver 14 to control the receiver 14. The example receiver 14 may further include one or more network interfaces 264 for communication over at least one network such as the Internet, a WAN, a LAN, a PAN etc. under control of one or more processors 266. Thus, the interface 264 may be, without limitation, a Wi-Fi transceiver, which is an example of a wireless computer network interface, such as but not limited to a mesh network transceiver. The interface 264 may be, without limitation, a Bluetooth® transceiver, Zigbee® transceiver, Infrared Data Association (IrDA) transceiver, Wireless USB transceiver, wired USB, wired LAN, Powerline or Multimedia over Coax Alliance (MoCA). It is to be understood that the processor 266 controls the receiver 14 to undertake present principles, including the other elements of the receiver 14 described herein such as, for instance, controlling the display 258 to present images thereon and receiving input therefrom. Furthermore, note the network interface 264 may be, e.g., a wired or wireless modem or router, or other appropriate interface such as, e.g., a wireless telephony transceiver, or Wi-Fi transceiver as mentioned above, etc.

In addition to the foregoing, the receiver 14 may also include one or more input ports 268 such as a high definition multimedia interface (HDMI) port or a USB port to physically connect (using a wired connection) to another CE device and/or a headphone port to connect headphones to the receiver 14 for presentation of audio from the receiver 14 to a user through the headphones. For example, the input port 268 may be connected via wire or wirelessly to a cable or satellite source of audio video content. Thus, the source may be a separate or integrated set top box, or a satellite receiver. Or, the source may be a game console or disk player.

The receiver 14 may further include one or more computer memories 270 such as disk-based or solid-state storage that are not transitory signals, in some cases embodied in the chassis of the receiver as standalone devices or as a personal video recording device (PVR) or video disk player either internal or external to the chassis of the receiver for playing back audio video (AV) programs or as removable memory media. Also, in some embodiments, the receiver 14 can include a position or location receiver 272 such as but not limited to a cellphone receiver, global positioning satellite (GPS) receiver, and/or altimeter that is configured to e.g. receive geographic position information from at least one satellite or cellphone tower and provide the information to the processor 266 and/or determine an altitude at which the receiver 14 is disposed in conjunction with the processor 266. However, it is to be understood that that another suitable position receiver other than a cellphone receiver, GPS receiver and/or altimeter may be used in accordance with present principles to determine the location of the receiver 14 in e.g. all three dimensions.

Continuing the description of the receiver 14, in some embodiments the receiver 14 may include one or more cameras 274 that may include one or more of a thermal imaging camera, a digital camera such as a webcam, and/or a camera integrated into the receiver 14 and controllable by the processor 266 to gather pictures/images and/or video in accordance with present principles. Also included on the receiver 14 may be a Bluetooth® transceiver 276 or other Near Field Communication (NFC) element for communication with other devices using Bluetooth® and/or NFC technology, respectively. An example NFC element can be a radio frequency identification (RFID) element.

Further still, the receiver 14 may include one or more auxiliary sensors 278 (such as a motion sensor such as an accelerometer, gyroscope, cyclometer, or a magnetic sensor and combinations thereof), an infrared (IR) sensor for receiving IR commands from a remote control, an optical sensor, a speed and/or cadence sensor, a gesture sensor (for sensing gesture commands) and so on providing input to the processor 266. An IR sensor 280 may be provided to receive commands from a wireless remote control. A battery (not shown) may be provided for powering the receiver 14.

The companion device 16 may incorporate some or all of the elements shown in relation to the receiver 14 described above.

The methods described herein may be implemented as software instructions executed by a processor, suitably configured application specific integrated circuits (ASIC) or field programmable gate array (FPGA) modules, or any other convenient manner as would be appreciated by those skilled in those art. Where employed, the software instructions may be embodied in a non-transitory device such as a CD ROM or Flash drive. The software code instructions may alternatively be embodied in a transitory arrangement such as a radio or optical signal, or via a download over the Internet.

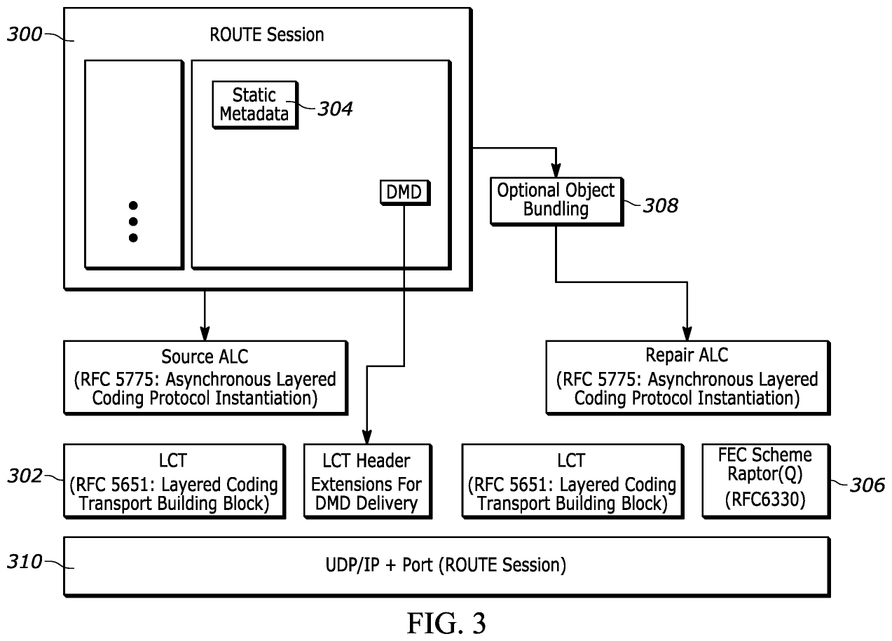

Now referring to FIG. 3, a ROUTE session 300 is established at an ATSC 3.0 transmitter that delivers layered coding transport (LCT) packets 302. These packets may carry source objects or FEC repair data. From a top-down approach, a source protocol consists of one or more LCT channels, each carrying delivery objects and, optionally, object metadata 304. The metadata may be statically delivered in signaling metadata or may be dynamically delivered, either as a compound object in the entity mode or as LCT extension headers in packet headers. The packets are carried in ROUTE using a specific FEC scheme 306 that permits flexible fragmentation of the object at arbitrary byte boundaries. In addition, delivery objects may be FEC protected, either individually or in bundles 308. In either case, the bundled object is encoded and the repair symbols are delivered via a ROUTE session over UDP/IP 310. By themselves, or in combination with any received source packets, the received repair symbols permit the recovery of delivery object bundles. Note that one or more repair flows may be generated, each with different characteristics, for example to support different latency requirements, different protection requirements, etc.

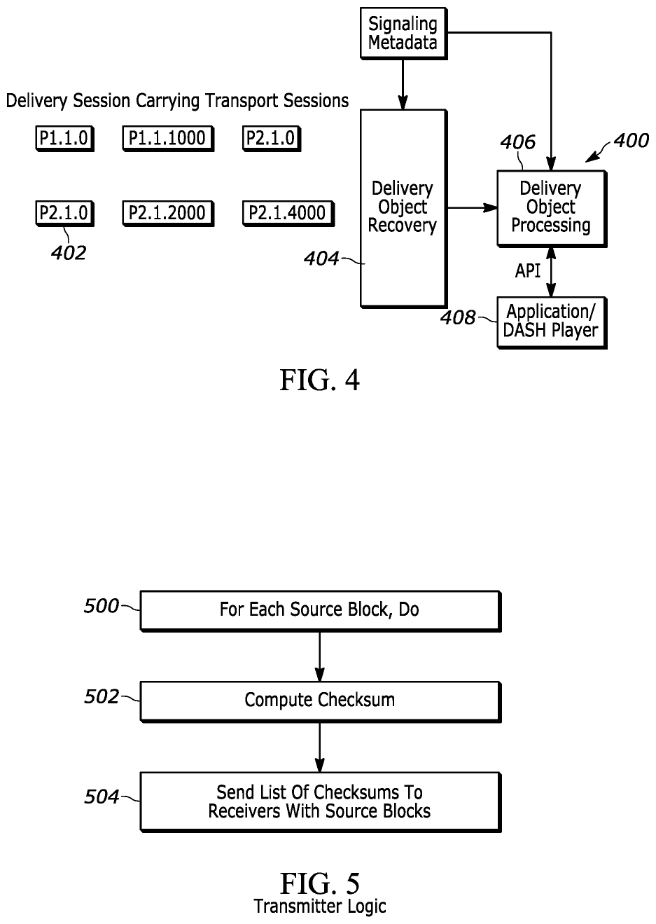

FIG. 4 illustrates the basic receiver operation. A receiver 400 such as any appropriately configured receiver herein receives packets 402 and filters those packets accordingly. From the ROUTE session and each contained LCT channel, the receiver regenerates delivery objects 404 from the ROUTE session and each contained LCT channel. The delivery objects are in turn passed to the appropriate handler 406 for further data processing for use by an application or a media player 408.

Refer now to FIG. 5. Commencing at block 500, an ATSC 3.0 or other appropriate digital TV transmitter such as a digital OTA transmitter, for each source block of a datacast file, computes a checksum at block 502. In one example the checksum may be a 32 bit cyclic redundancy check (CRC) value. In another embodiment a message digest (MD)-5 checksum may be used. Proceeding to block 504, a list of the checksums is generated and sent with the source blocks, e.g., via OTA. In an example implementation, the list of checksums may be included in the RepairFlow element of the service transport session instance description (S-TSID) since only RepairFlow element and AL-FEC provides the breakdown of the data into source blocks and has no meaning outside of RepairFlow element. Each checksum in the list is thus correlated with the source block to which it pertains.

Accordingly, present principles apply a checksum on a per source block basis to minimize the effort required of a receiver by improving the likelihood of success after further attempts around a carousel where sufficient repair blocks may not always be available for every source block. This is especially true with large files where RFC 6330 only applies repair bytes at the end of the entire file.

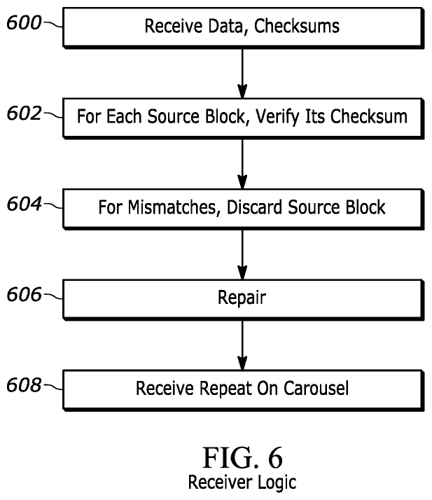

FIG. 6 illustrates receiver-side logic. Commencing at block 600, the source blocks and list of checksums are received. In other words, to improve robustness, the receiver receives a respective checksum for each source block, and each checksum is verified at block 602, for example by recomputing the checksum using the content of the received source block and comparing the recomputed checksum with the checksum for the source block as received in the list from the transmitter. This allows the receiver to discard only a portion of the data at block 604 as defined by the length of this source block in the AL-FEC parameters. That is, at block 604 the receiver discards source blocks for which the recomputed checksum does not match the received checksum.

Moving to block 606, for source blocks with mismatched checksums the receiver may attempt repair of the source block by fetching the source block data from a server (as location specified in other signaling). That is, the receiver may supplement the missing packets and bad source blocks through a TCP/IP connection when a server, and the connection to the server, is available, whilst minimizing the data overhead on the unicast server. Or, the receiver can simply wait to receive the data again on a broadcast carousel at block 608.

The table below illustrates repair flow elements, data types, and descriptions as may be sent in an S-TSID. Of relevance to present principles are the two data flow elements @percentRepair and @checksumList. @percentRepair can be, in one implementation, a 16-bit unsigned integer that equates to the maximum ratio of repair symbols to source symbols as a percentage. Absence of this attribute means the AL-FEC repair data size is not provided.

On the other hand, @checksumList is an optional space separated list of, for example, 32 bit unsigned integers in hexadecimal format that equates to the calculated CRC32 checksums of each source block. This list may be used by the receiver to determine the accuracy of received and/or repaired data in a source block. In its absence the integrity of the complete received and/or repaired file may be available through the optional FDT-Instance MD5 Checksum. However, the CRC32 checksum list, when present, allows the receiver to more finely assess the need to replace data at a source block level of resolution.

| Element or | | | |
|---|---|---|---|
| Attribute Name | Use | Data Type | Description |
| @appContextIdList | 0 . . . 1 | afdt:uriList | A space-separated list of URIs representing one |
| | | | or more unique Application Context Identifiers. |
| @filterCodes | 0 . . . 1 | afdt:listOfUnsignedInt | A space-separated list of 32-bit unsigned integers |
| | | | representing Filter Codes that apply to this file. |
| @maxCacheMemory | 0 . . . 1 | unsignedint | The maximum memory required at any time by the |
| | | | receiver to cache the data when the packets are |
| | | | being delivered out-of-order. |

ATSC 3.0 A/331 Table 6.2 describes the S-TSID table and these new AL-FEC parameters can be added as shown below.

| Element or | | | |
|---|---|---|---|
| Attribute Name | Use | Data type | Description |
| RepairFlow | | stsid:rprFlowType | Repair flow carried in the LCT channel. |
| FECParameters | 0 . . . 1 | | FEC Parameters corresponding to the repair flow. |
| @maximumDelay | 0 . . . 1 | unsignedInt | Maximum delivery delay between any source packet |
| | | | in the source flow and the repair flow. |
| @overhead | 0 . . . 1 | unsignedShort | FEC overhead in a ROUTE packet represented as a |
| | | (percentage) | percentage. |
| @minBuffSize | 0 . . . 1 | unsignedInt | Required buffer size to handle all associated objects |
| | | | that are assigned to a super-object. |
| @fecOTI | 1 | hexBinary | FEC-related information associated with an object as |
| | | | well as FEC information associated with the |
| | | | encoding symbols of the object and is to be included |
| | | | within this declaration and applies to all repair |
| | | | packets with the repair flow. |
| @percentRepair | 0 . . . 1 | UnsignedShort | The maximum ratio of repair symbols to source |
| | | | symbols as a percentage |
| @ChecksumList | 0 . . . N | unsignedInts | List of CRC32 hexadecimal formatted checksums for |
| | | | each source block in the order of the source blocks. |
| ProtectedObject | 0 . . . N | | List of the source flow(s) protected by this repair flow |
| | | | and the details on how the protection is done. It also |
| | | | defines how certain delivery objects of a collection |
| | | | of objects are included in the repair flow. |
| @sessionDescription | 0 . . . 1 | string | Specifies the session description information for the |
| | | | source flow. |
| @tsi | 1 | unsignedInt | The Transport Session Identifier (TSI) for the source |
| | | | flow to be protected. |
| SourceTOI | 1 . . . N | | The Transport Object Identifier (TOI) value(s) of the |
| | | | delivery object(s) corresponding to the TOI of a |
| | | | given FEC (super-)object delivered by the repair flow. |
| @x | 0 . . . 1 | unsignedShort | Value of the constant X for use in deriving the TOI of the |
| | | | delivery object from the TOI of the FEC (super-)object. |
| @y | 0 . . . 1 | unsignedShort | Value of the constant Y for use in deriving the TOI of the |
| | | | delivery object from the TOI of the FEC (super-)object. |

It will be appreciated that whilst present principals have been described with reference to some example embodiments, these are not intended to be limiting, and that various alternative arrangements may be used to implement the subject matter claimed herein.

1. A method, comprising:
computing respective checksums for each source block of a digital file, the digital file comprising plural source blocks each of which has a respective checksum computed; and
transmitting the plural source blocks and a list comprising the computed checksums to at least one receiver using digital television transmission, the list being included in a RepairFlow element of a service transport session instance description (S-TSID).

2. The method of claim 1, comprising:
at a digital receiver, applying a checksum on a per source block basis to improve likelihood of success after further attempts around a broadcast carousel at least in part by:
receiving the plural source blocks and the list;
verifying each computed checksum from the list;
discarding source blocks for which the respective computed checksums are not verified and not discarding source blocks for which the respective computed checksums are verified;
for source blocks with unverified computed checksums, fetching the source blocks from at least one server having a network location specified in signaling of the digital television, or waiting to receive the source blocks again on a broadcast carousel, or both fetching the source blocks from the at least one server and waiting to receive the source blocks again on a broadcast carousel.

3. The method of claim 2, comprising:
fetching the source blocks from the at least one server.

4. The method of claim 2, comprising:
waiting to receive the source blocks again on a broadcast carousel.

5. The method of claim 2, wherein verifying each computed checksum comprises:
recomputing the respective checksum using content of the respective source block; and
comparing the recomputed checksum with the respective computed checksum for the source block as indicated in the list.

6. The method claim 2, wherein the digital receiver comprises an advanced television systems committee (ATSC) 3.0 receiver.

7. A digital television apparatus, comprising:
at least one receiver configured to receive digital television from a digital television transmitter system, the receiver comprising at least one processor programmed with instructions for:
receiving, from at least one digital television transmitter, plural source blocks of a single file and a list comprising respective calculated checksums, each calculated checksum being associated with a respective source block of the single file;
verifying each calculated checksum;
discarding source blocks for which the respective calculated checksums are not verified and not discarding source blocks for which the respective calculated checksums are verified; and
for source blocks with unverified calculated checksums, fetching the source blocks from at least one server having a network location specified in signaling of the digital television, or waiting to receive the source blocks again on a broadcast carousel, or both fetching the source blocks from the at least one server and waiting to receive the source blocks again on a broadcast carousel.

8. The digital television apparatus of claim 7, wherein the instructions are executable for:
fetching the source blocks from the at least one server.

9. The digital television apparatus of claim 7, wherein the instructions are executable for:
waiting to receive the source blocks again on a broadcast carousel.

10. The digital television apparatus of claim 7, wherein the instructions are executable for executing the verifying by:
recomputing the checksum using content of the respective source block; and
comparing the recomputed checksum with the computed checksum for the source block as indicated in the list.

11. The digital television apparatus of claim 7, wherein the digital television receiver comprises an advanced television systems committee (ATSC) 3.0 receiver.

12. A digital television apparatus, comprising:
at least one transmitter comprising at least one processor programmed with instructions to configure the processor for:
computing a respective checksum for each source block of a digital file, the digital file comprising plural source blocks for which respective checksums are computed; and
transmitting the source blocks of the digital file and a list comprising the respective checksums to at least one receiver using digital television transmission.

13. The digital television apparatus of claim 12, wherein the list is included in a service transport session instance description (S-TSID).

14. The digital television apparatus of claim 13, wherein the list is included in a RepairFlow element of the S-TSID.

15. The digital television apparatus of claim 12, wherein the checksums comprise cyclic redundancy code (CRC) 32 bit checksums.

16. The digital television apparatus of claim 12, wherein the checksums comprises message digest (MD)5 checksums.

17. The digital television apparatus of claim 12, wherein the transmitter comprises an advanced television systems committee (ATSC) 3.0 transmitter.

18. The digital television apparatus of claim 12, comprising:
a digital receiver, the digital receiver configured to:
apply a respective checksum on a per source block basis at least in part by:
receiving the plural source blocks and the list;
verifying each computed checksum from the list;
discarding source blocks for which the respective computed checksums are not verified and not discarding source blocks for which the respective computed checksums are verified; and
for source blocks with unverified computed checksums, fetching the source blocks from at least one server.

19. The digital television apparatus of claim 18, wherein verifying each computed checksum comprises:
recomputing the respective checksum using content of the respective source block; and
comparing the recomputed checksum with the respective computed checksum for the source block as indicated in the list.

20. The digital television apparatus of claim 18, wherein the digital receiver comprises an advanced television systems committee (ATSC) 3.0 receiver.
